(19) United States
(12) Patent Application Publication
(10) Pub. No.: US 2003/0063663 A1
(43) Pub. Date: Apr. 3, 2003

(54) Multistage equalizer that corrects for linear and nonlinear distortion in a digitally-modulated signal

(76) Inventor: Paul Henry Bryant, Encinitas, CA (US)

Correspondence Address: TERRANCE A. MEADOR, GRAY CARY WARE & FREIDENRICH, LLP, 4365 EXECUTIVE DRIVE, SUITE 1100, SAN DIEGO, CA, 92121-2133, US

(21) Appl. No.: 09/968,063

(22) Filed: Oct. 1, 2001

(51) Int. Cl. H03H 7/30

(52) U.S. Cl. 375/229

(57) ABSTRACT

In a digital communication system or a digital storage system where digitally-modulated signals are transmitted in a signal path including a dispersive channel, a multistage equalizer has two or more stages connected in a sequence to correct for the effects of linear distortion and nonlinear distortion encountered during transmission through the signal path. The two or more stages are each characterized by a respective function, and the sequence is characterized by alternation of the functions of the two or more stages between linear and nonlinear.

### CROSS REFERENCE TO RELATED APPLICATION

This application is related to U.S. application Ser. No. ______ , entitled, PEAK TO AVERAGE POWER RATIO REDUCTION IN A DIGITALLY-MODULATED SIGNAL, which is commonly owned and concurrently filed herewith, and which is incorporated herein by this reference.

### BACKGROUND OF THE INVENTION

The invention concerns the transmission or storage of information by digitally-modulated means in the presence of linear and non-linear distortion. More particularly, the invention concerns the correction of digitally-modulated signals for the effects of linear and non-linear distortion.

Digital modulation refers to the use of digital codes to vary one or more characteristics of one or more carriers in a way that plants information into the variation. In this regard, a modulated carrier “carries” the information. An unmodulated carrier may have zero frequency, that is, it may have a constant level such as voltage, or it may be time-varying, like a sine wave. The variation produced by digital modulation may be in one or more of the amplitude, phase, and frequency of a carrier. The purpose of digital modulation is to have information transmitted via the modulated signal or signals in, for example, a communication channel or a data storage channel.

A signal may exist in analog form or in digital form. In analog form, the signal consists of a continuous, time-varying amplitude in the form of a voltage or a current. In digital form, the signal consists of a sequence of real numbers, often called a time series. Each real number has a digital form, in the numeric sense and in the waveform sense. This sequence of real numbers can be interpreted as a sequence of measured amplitudes of the analog signal. It should be noted that the concept of a signal carrying digital information is distinct from whether that signal is represented in digital or analog form.

For clarity, “transmission” of digitally modulated signals refers to their passage through a signal path that includes a channel plus any other elements at either end of the channel through which the signals must pass in order to be placed in or received from the channel. The term “channel” means a physical medium used to conduct or store signals. Examples of channels include twisted pairs of wires, coaxial cables, optical fibers, electromagnetic waves in space, magnetic recording media, optical recording media, and so on. In addition to a channel, a signal path includes components or elements that are coupled to either end of a channel in order to feed digitally-modulated signals into the channel or to receive them from the channel.

A single channel may provide oppositely-directed transmission for two signal paths. Two-way transmission through a single, shared channel requires means in the channel for separating outgoing from incoming signals at each end of the channel; it may also require repeater means in the channel capable of separating and then recombining oppositely-directed signals intermediate the ends of the channel.

Transmission of digitally-modulated signals in a system designed for digital communication or data storage often assails those signals with linear distortion and nonlinear distortion. Such distortion degrades the signals and requires corrective measures when the signals are received in order that information can be reliably extracted from the signals.

Linear distortion changes the shapes of signals as they are transmitted. In this regard, a channel through which the signals are transmitted disperses the amplitudes and phases of the components of the signals to unequal degrees that are dependent upon the frequencies of the components. The result is smearing in the received signals, which can lead to intersymbol interference. Such a channel is denominated a “dispersive channel”. A channel in which the output changes in direct proportion to changes made in the input signal or some component thereof may be considered a “linear channel”. However in such a channel the components of different frequencies may travel through the channel at different speeds and be attenuated by different factors. These effects of linear distortion can be ameliorated by equalization of received signals. A linear equalizer removes or reduces the effects of linear distortion by making adjustments in the components of a received signal to compensate for the changes made in those components by transmission through the channel.

Nonlinear distortion occurs when the proportionality or linearity with which a signal is being distorted is violated to some degree. Typically such nonlinear effects are not distributed throughout the signal path, but rather are concentrated at particular sites. Some examples of nonlinear distortion include: (1) a driver at the input to a channel or a mid-channel repeater that exhibits some nonlinearity dependant on the signal amplitude or on the derivative of the amplitude (slew rate); (2) a corroded contact in a channel that has some nonlinear (non-ohmic) characteristics; (3) a transformer in a channel that exhibits some significant nonlinearity, perhaps related to magnetic hysteresis in its core. It is also possible that a nonlinear distortion of known characteristics of a digitally-modulated signal could be introduced intentionally in order to improve some performance factor of a communications or data storage process (with the assumption, of course, that the effects of this distortion can later be successfully removed).

In a bidirectional communications channel, the incoming signal can be corrupted by a distorted echo of the outgoing signal. The echo can arise from impedance mismatching at various points in the signal path. Linear and nonlinear distortion of the echo may result from the usual sources described previously. To attempt to remove the corruption, a model of the distorted echo can be generated from the outgoing signal. This is subtracted from the corrupted incoming signal, thus removing the echo and leaving a clean incoming signal.

A particularly intractable problem in the transmission of digitally-modulated signals has been the correction of such signals after being subjected to one or more sources of nonlinear distortion before or during transmission in an otherwise linear signal path.

### SUMMARY OF THE INVENTION

The invention, a multistage equalizer, provides an effective solution to the problem of correcting signals to remove the effects of nonlinear distortion imposed at one or more locations in an otherwise linear signal path. The location and characteristics of the nonlinear effect(s) need not need be known in advance, as the multistage equalizer has adjustable parameters which allow it to adapt to a continuum of different situations. The stages are typically connected in a sequence in which the function of the stages alternates between linear and nonlinear, with two or more stages in the sequence. One or more linear stages are provided to remove linear distortion imposed on the signal in some particular section of the signal path in which no significant nonlinear effects are present. One or more nonlinear stages are provided to correct distortion caused by particular localized nonlinear effects. To the extent that nonlinear distortion is localized, it can be more accurately modeled and corrected by a nonlinear stage characterized by a function with a relatively small number of adjustable parameters.

In the case where there is a single primary source of nonlinear distortion located somewhere in the signal path, the preferred embodiment of the multistage equalizer has three stages in the sequence linear, nonlinear, linear. In this case the multistage equalizer includes a first stage characterized by a function that operates on signals received from the dispersive channel to produce first results corrected for linear distortion which occurred in the portion of the signal path between the location of the source of nonlinear distortion and the end of the signal path. The multistage equalizer further includes a second stage coupled to the first stage and characterized by a second function that operates on the first results to produce second results corrected for nonlinear distortion produced by the source of nonlinear distortion. A third stage, which is coupled to the second stage, is characterized by a third function that operates on the second results to produce third results corrected for linear distortion in the portion of the signal path between its beginning and the location of the source of nonlinear distortion. The third results are the output of the multistage equalizer. The output can be processed to yield digital information. This structure of the multistage equalizer can easily be generalized to cases in which there is more than one site in the signal path where nonlinear distortion occurs. Such cases can result in more than three stages for the multistage equalizer. It is most likely, in these cases, that the first and last stages will both be linear; the exception occurs when a nonlinearity is located at the exact start or end of the signal path, in which case a linear stage may be omitted.

The functions which characterize the stages may contain adjustable parameters. An equalizer controller is coupled to the linear and nonlinear stages for setting these parameters to values that minimize a particular error measure. An error measure generator is coupled to the equalizer controller for generating the error measure. Generally, the adjustment of the function parameters utilizes an optimization process that seeks to minimize the error measure.

### BRIEF DESCRIPTION OF THE DRAWINGS

FIGS. 1a and 1b show general functions of the multistage equalizer of this invention in two general configurations. FIG. 1a illustrates the multistage equalizer in a forward configuration to correct signal distortion such as might be caused by passage through a communications channel or by passage into and out of a data storage device. FIG. 1b illustrates the multistage equalizer in a reverse configuration that, for example, has application to echo-cancellation.

FIG. 2 is a block diagram of elements of a digital communication system that incorporates a multistage equalizer according to the invention.

FIGS. 3a-3c illustrate three respective embodiments of the multistage equalizer of the invention.

FIG. 4 illustrates one embodiment of a linear stage of the multistage equalizer of the invention.

FIGS. 5a-5f illustrate respective embodiments of a nonlinear stage of the multistage equalizer.

FIGS. 6a and 6b illustrate, respectively, a Fourier transform and a discrete frequency-domain embodiment of a linear stage used in the multistage equalizer in the system of FIG. 7a.

FIG. 7a is a block diagram of an exemplary digital communication system using DMT modulation that incorporates the multistage equalizer of the invention.

FIG. 7b shows the improvement, using a multistage equalizer according to the invention, obtained in the recovery of data transmitted through a twisted pair line containing an inserted nonlinear element.

FIG. 8 is a generalized flow diagram illustrating an optimization procedure according to the invention for initializing and setting values of parameters in functions that characterize the stages of a multistage equalizer.

FIG. 9 is a flow diagram illustrating an optimization procedure according to the invention for initializing and setting values of parameters in functions that characterize the stages in the multistage equalizer in the system of FIG. 7a.

### DETAILED DESCRIPTION OF THE PREFERRED EMBODIMENTS

The invention is illustrated in one or more of the above-described drawings, and is disclosed in detail in the following description. Although these illustrations and the description may show and describe elements that are “connected”, this is done in order to establish a sequence with respect to those elements, and to set up a basis for discussion of how those elements act cooperatively. Accordingly, it is within the scope of the invention to place other elements not illustrated or described herein in the connections between elements that are illustrated and described.

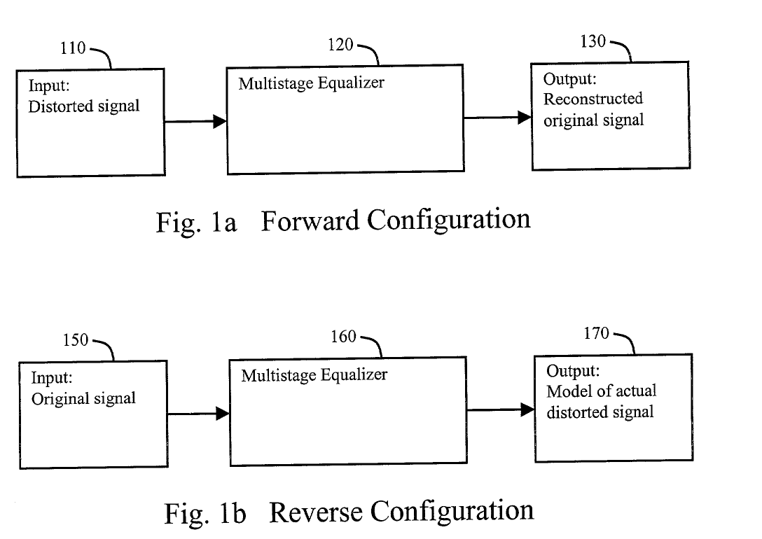

A multistage equalizer according to this invention can be used in forward and reverse deployments. Some particular examples are (1) the receiver for a data communications channel, (2) in the recovery section of a data storage system, and (3) in an echo cancellation apparatus for a two-way data communications system. The first and second of these examples would utilize a “forward deployment” of the multistage equalizer in the configuration shown in FIG. 1a. Here the signal from a communication channel or a storage device 110 is processed by the multistage equalizer 120 to remove the effects of dispersion and nonlinear distortion in order to produce a reconstructed signal 130. In the third example, a “reverse deployment” of the multistage equalizer 120 is utilized as shown in FIG. 1b. In echo-cancellation the goal is to remove any residual echo of an outgoing signal from an incoming signal. This echo typically results from an impedance mismatch with the communication channel. The method is to process an outgoing signal 150 with the multistage equalizer 160 to create a replica 170 of the echo of the outgoing signal. This replica is then subtracted from the incoming signal to remove the unwanted echo.

In the remainder of this detailed description, a multistage equalizer is deployed in the forward configuration in a digital communication system in which information is carried on digitally modulated signals that are transmitted or propagated in a channel. Those skilled in the art will have no difficulty in adapting this deployment to other situations where multistage equalization may be useful, in either of the forward and reverse configuration, such as data recovery for digital magnetic recording or in an echo cancellation apparatus. The channel may be embodied in any one of a plurality of media. In most cases such channels are capable of handling simultaneous data transmission in both directions. However, for simplicity, but without limiting the possible applications of this invention, this description will concern what happens to the signal going in one direction through the channel. Thus, description will be given only of the transmission circuitry on one end of the channel (which may be called the “input end”) and the reception circuitry on the other (also, the “output end”). Since the channel is linearly dispersive, it may be referred to as “linear” or as “dispersive”. Prior to or during transmission through the channel, the signals may be subjected to nonlinear distortion. As a result, the linear distortion that the channel imposes may act upon not only the desirable components of the signals, but also upon undesirable components introduced by one or more sources of nonlinear distortion. The linear distortion compounds the effects of nonlinear distortion, making signal correction that much more difficult. The multistage equalizer of this invention is particularly applicable in cases where the nonlinear distortion is localized, i.e. it occurs at or near one or more locations in an otherwise linear signal path rather than being distributed throughout the signal path.

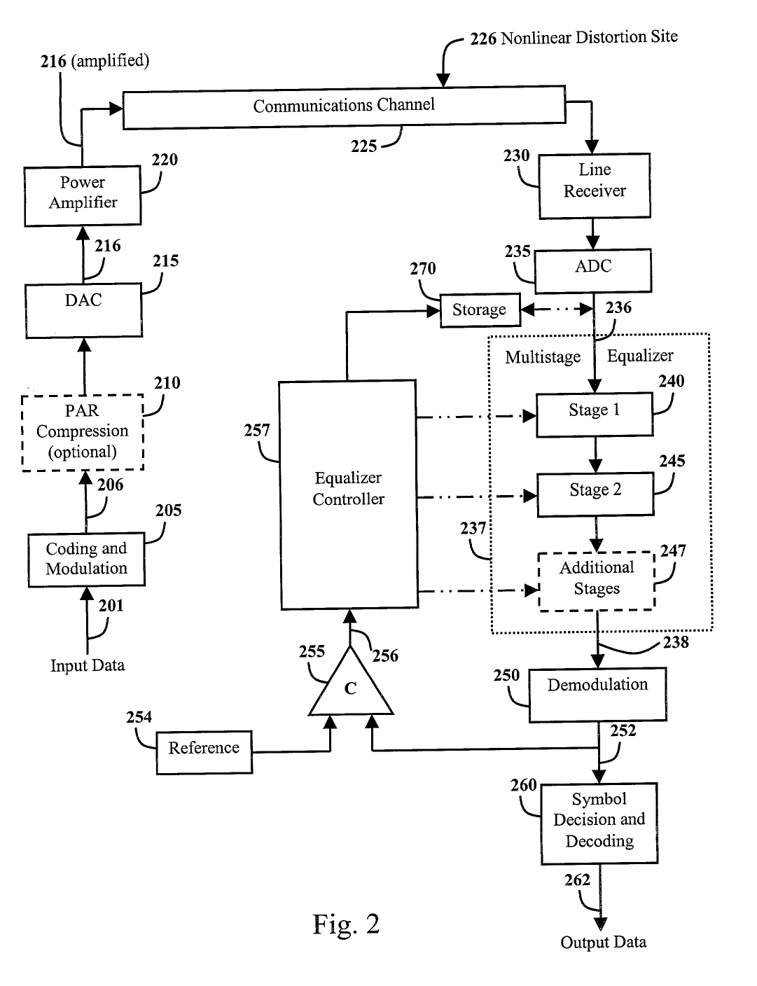

Refer to FIG. 2, which is a block diagram of a digital communication system wherein input data 201 to be transmitted to a destination is provided to coding and modulation circuitry 205. (Note that the processing of digital information can be done either in hardware or software—this applies to all parts of FIG. 2, except those with reference numbers from 215 through 235 where the signal is in analog form.) The circuitry 205 maps the input data 201 to a digital code. This coded data is broken down into a sequence of symbols. Each symbol represents a certain number of bits of digital data. These symbols are then used to modulate a carrier or set of carriers in one or more of amplitude, frequency, and phase. For every allowed symbol there will be a unique setting for these carrier parameters which will remain fixed for a certain length of time before switching to those representing the next symbol. Digital modulation signals 206 are produced by the circuitry 205. These signals 206 represent, in digital form, modulated carriers that are to be transmitted. The digital modulation signals 206 are provided to a digital-to-analog converter (DAC) 215. The DAC 215 converts the digital modulation signals to analog form 216. The signals 216 are coupled from the DAC 215 to the input of a power amplifier 220. The power amplifier 220 drives the medium in which a channel 225 is embodied. Typically the power amplifier 220 is part of a hybrid circuit (“hybrid”)—the term commonly used for a device that allows simultaneous transmission and reception of data on a single channel. The medium is dispersive, and linearly distorts the signals as they propagate through it. The propagated signals are coupled from the channel 225 to a line receiver 230 (also typically part of a hybrid circuit). The line receiver 230 is coupled to an analog-to-digital converter (ADC) 235 that converts the incoming data from analog form to digital form. These signals (referred to as “received digital modulation signals”) 236 are then processed by a multistage equalizer 237 that embodies the invention.

The multistage equalizer 237 is constituted of a sequence of linear and nonlinear stages. The multistage equalizer has at least two stages 240 and 245; it includes additional stages 247 when necessary. Each of the stages is characterized by a respective function that may contain adjustable parameters. These adjustable parameters allow the performance of the stage to be optimized for particular channel characteristics. Details of these stages and of the overall operation and structure of the multistage equalizer 237 are disclosed later.

Following correction by the multistage equalizer 237, the corrected digital modulation signals 238 are provided to demodulation circuitry 250, which extracts the carrier modulation parameters 252. The carrier modulation parameters 252 are provided to symbol decision and decoding circuitry 260. The symbol decision and decoding circuitry 260 compares the carrier modulation parameters to those corresponding to the allowed symbol set, and selects the symbol that most closely matches. The symbol is converted back into digital data and decoded to produce the output data 262.

In order to optimize the performance of the multistage equalizer 237, a known sequence of symbols may be sent through the channel 225. The extracted sequence of carrier modulation parameters 252 for this known sequence is connected to a comparator 255. The comparator 255 compares the received values to reference values 254 corresponding to the known sequence and produces an error measure 256 having a value based upon how well the received modulation parameters 252 compare with these reference values. The error measure 256 is coupled to an equalizer controller 257. The equalizer controller 257, in response to the value of the error measure 256, sets and changes values of parameters, and provides the values to the stages of the multistage equalizer 237. These parameters are explained later in more detail; however, it is sufficient here to say that they are components of functions that characterize the stages of the multistage equalizer 237. The equalizer controller employs or executes a procedure for setting these parameters. The procedure may be embodied for example in an iterative optimization process in which a data set collected at the output of the ADC 235 is processed through the multistage equalizer 237 a number of times as the parameters values are optimized. The data set may be transmitted once through the signal path 215, 216, 220, 225, 230, captured at the output of the ADC 235 and stored at a storage location 270.

There are many sources in the system of FIG. 2 that impose distortion on signals transmitted through the channel 225. Linear distortion typically results from transmission through the medium of which the channel 225 is constituted. Linear distortion may also result from other components in the signal path. Nonlinear distortion may be imposed by, for example, a source 226 in the channel 225. Nonlinear distortion may also result from processing by elements 215, 220, 230, and 235. Nonlinear distortion may also be intentionally imposed in order to accomplish some beneficial objective.

One source of intentional nonlinear distortion may be understood with reference to a peak-to-average power ratio (PAR) limiter 210, an optional element of the system illustrated in FIG. 2. Such an element might be desirable, for example, in the case where the system of FIG. 2 is embodied in a multicarrier system. Here, it may be advantageous to limit the PAR by means of a known nonlinear (or piecewise linear) compression function applied by the PAR limiter 210. The structure, function, and operation of this element are set forth in detail in commonly-owned application Ser. No. ______, entitled ______. Optionally, the PAR limiter 210 may be inserted into the system of FIG. 2 between the coding and modulation circuitry 205, and the DAC 215 to reduce the PAR of the analog signals produced by the DAC 215 and amplified by the power amplifier 220. The beneficial results of this intentional nonlinear distortion include reduction of power consumed in central stations and improvement of the resolution and linearity of digital-to-analog and analog-to-digital conversion.

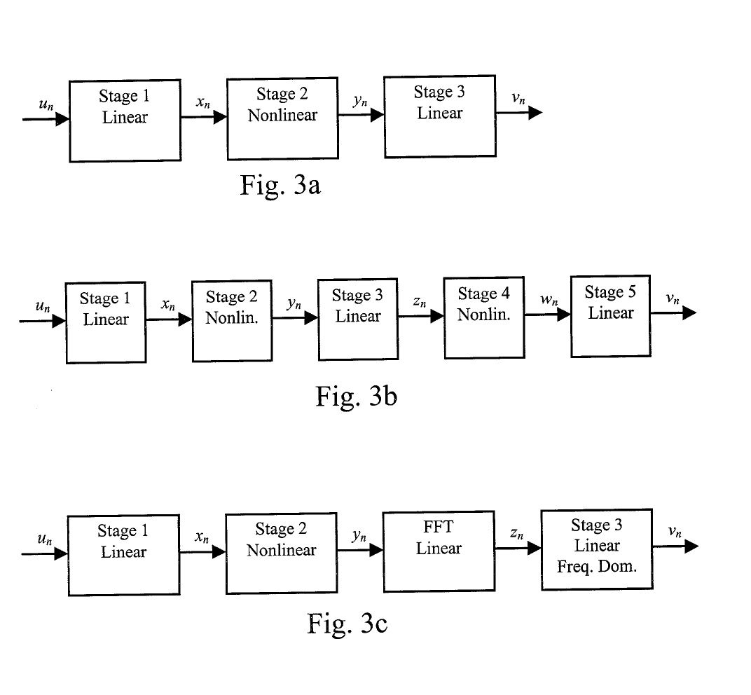

The structure, function, and operation of a multistage equalizer 237 according to this invention may be understood with reference to FIGS. 3a-3c, 4, 5a-f, 6a and 6b. The multistage equalizer consists of a sequence of at least two stages. Each stage takes one digital time series x₁, X₂, X₃, . . . as input and produces another one y₁, y₂, y₃, . . . as output. Particular elements of the output series may depend on the values of more than one of the elements of the input series (e.g. yₙ could depend on Xₙ₋₂, Xₙ₋₁, Xₙ, Xₙ₊ₗ, and Xₙ₊₂). The stages are characterized by respective functions which may, if desired, depend on a number of settable parameters, not necessarily the same number for each stage. In the following, the stages are, in fact, described in terms of the functions which characterize them, with the understanding that the functions are entirely descriptive of the structures of the stages, as well as their operations. The settable parameters of the characterizing functions enable the multistage equalizer to adapt to a signal path including a channel with unknown or changeable characteristics. The stages are connected in a sequence, so that the input to the multistage equalizer is the input to the first stage, the output of the first stage is connected to the input of the second stage, the output of the second stage is connected to the input of the third stage, and so on until the last stage, the output of which is the output for the multistage equalizer. The stages may be categorized into two types: “linear” and “nonlinear” depending on whether or not an element of the output time series of a stage will always (and for all parameter settings) vary linearly (i.e. in direct proportion) to changes made to an element of the input time series of the stage. The multistage equalizer always conforms to a sequence with at least one linear and one nonlinear stage. Linear stages will typically have output values that depend on many input values, as is necessary to correct for channel dispersion. Nonlinear stages, on the other hand, will typically have output elements that depend only on one or a small number of input elements. The sequence of stages will usually alternate between the two types although this rule could possibly be violated in special cases.

In selecting a particular multistage equalizer architecture, the following guidelines are employed. Each nonlinear effect is assumed to act on a one-dimensional (or at least a low dimensional) dynamical variable, such as the amplitude of a signal or its first derivative, at some particular point in the channel. The design technique underpinning the multi-stage approach is based on the assumption that the channel can be characterized as a sequence of linear sections separated by these localized nonlinear effects. The details of these effects and their locations do not need to be known in advance. One of these effects will be nearest to the output end of the channel. The first step in the equalization process is to recreate the corresponding dynamical variable (or variables) from the signals output from the channel using a linear stage. Then the nonlinear distortion is removed from this dynamical variable (or variables) by a nonlinear stage that follows the linear stage; in many cases this nonlinear stage may be characterized by a power series expansion of a single variable having only a few terms. The output of this nonlinear stage is taken to represent the signal just prior to the nonlinear effect. If there is only one pronounced nonlinear effect in the channel, this output may be passed on to another linear stage by which the multistage equalizer recovers the input signal to the beginning of the channel. Thus, a three-stage structure with the sequence linear, nonlinear, linear shown in FIG. 3a is indicated. Otherwise, additional stages alternating between nonlinear and linear may be added until all nonlinearities have been corrected. FIG. 3b shows a sequence of five stages, which could be used to equalize a channel containing nonlinear effects occurring at two different locations in the channel. Note that usually the equalizer will begin and end with linear stages. An exception may be made in cases where one of the nonlinear distortion sites is at or near one of the channel ends, so that there remains no significant linear dispersion effects between this site and the end of the channel. (Such is the case when utilizing the PAR limiter 210 of FIG. 2, so the equalizer in this case could have as few as two stages in the sequence linear-nonlinear.) More complex architectures are possible, including ones with stages in parallel as well as in series, although at this time no practical case is known where these would be of use.

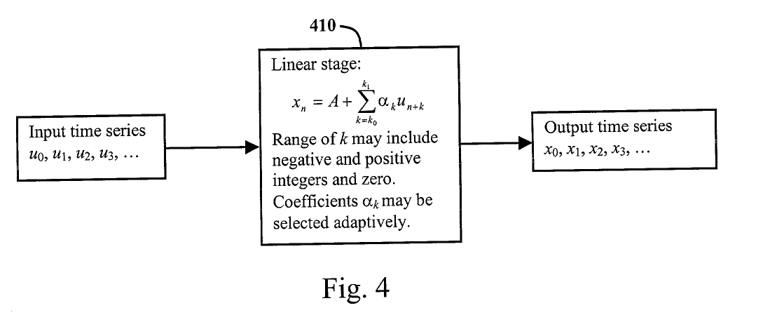

A preferred embodiment of a linear stage is illustrated in FIG. 4. The illustrated linear stage is a linear time-domain equalizer embodied here as a finite impulse response (FIR) filter. As those skilled in the art will appreciate, such an element may be characterized or described by the function with which it is implemented. In this case, the embodiment is implemented by the function 410, in which:

$${x}_{n} = A + {\sum }_{k = {k}_{0}}^{{k}_{1}} {α}_{k} {u}_{n + k}$$

With reference to FIGS. 2 as an example, using the function 410 shown in FIG. 4 as the first stage 240 of the multistage equalizer 237, the output of the ADC 235 is received by the first stage 240 as a time sequence of digital values u₀, u₁, u₂, u₃ . . . . In the function, each successive digital value is associated with a parameter, in this case, a coefficient αₖ, having a value that is combined (multiplied) with the digital value to yield a product. The range of the index k will typically include all integer values between chosen starting and ending values k₀ and k₁. Note that these values may be positive, negative, or zero. The values used will depend on the dispersion and other characteristics of a particular channel. If needed, a constant parameter A may be included as indicated to correct for shifts in the level of the signal. All of the products are summed and added to A to produce a single member of the output time sequence of digital values x₀, x₁, x₂, x₃ . . . . By shifting the association of each parameter to the digital value that is one step forward in the time sequence, the next member of the output sequence is generated and so on. This sequence constitutes the first results produced by the first stage of the multistage equalizer 237. The values of the coefficients are set and changed by the equalizer controller 257 in a manner described later in more detail.

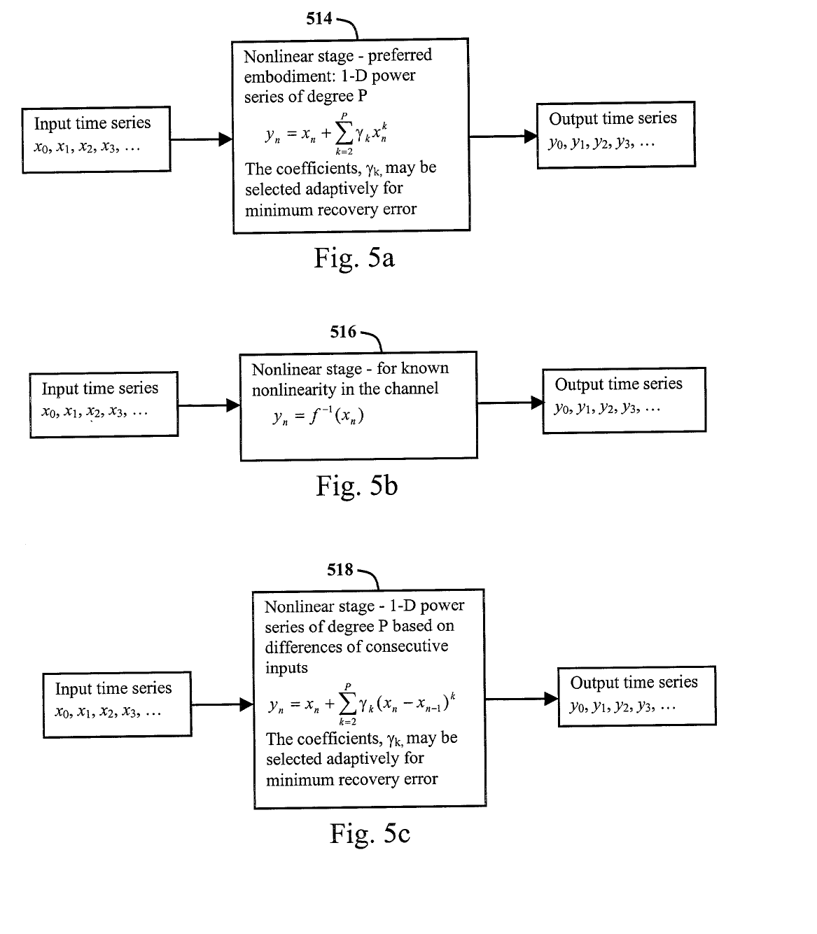

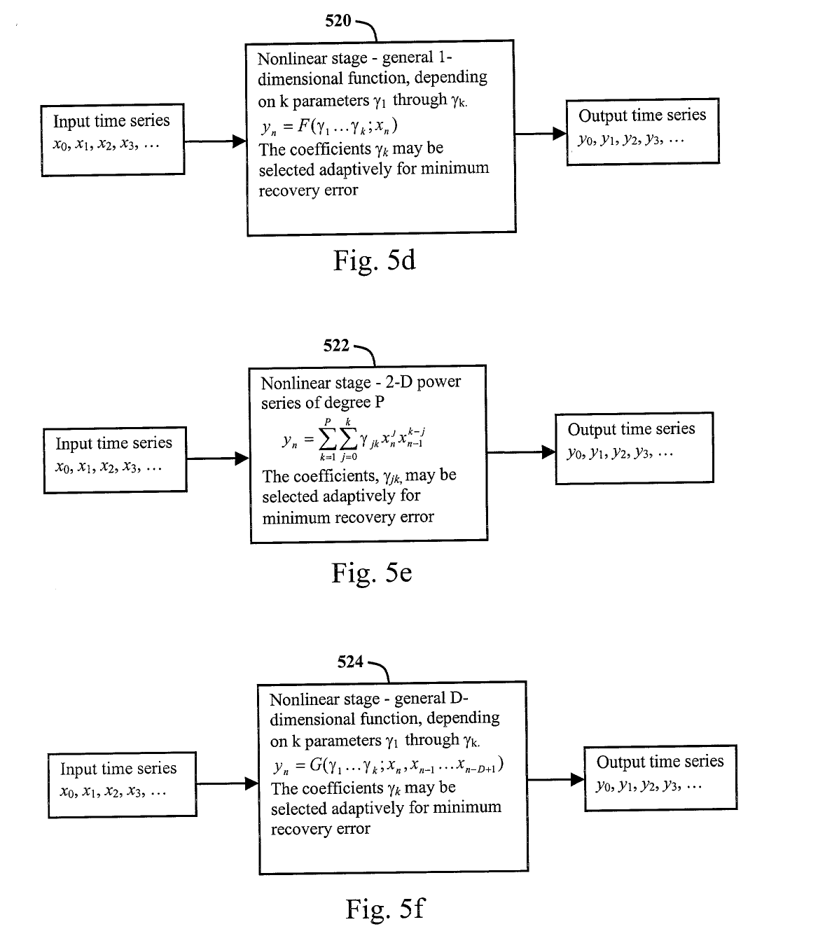

The second stage 245 (now assumed to be nonlinear) receives the first results as an input time sequence and produces the second results as an output time sequence y₀, y₁, y₂, y₃ . . . . With reference to FIGS. 2 and 5a-5f, a plurality of nonlinear stage embodiments may be understood. In FIG. 5a, the nonlinear stage is implemented by a basic power series function 514. This is the preferred embodiment for most cases, especially for amplitude based nonlinearities. This is a one-dimensional (1-D) stage, meaning that the output yₙ depends only on a single input xₙ. Having a low dimensionality makes this stage simple compared to the linear stage (FIG. 4) which in practice will often have a dimension or number of “taps” in the hundreds. The function 516 illustrated in FIG. 5b may characterize the nonlinear stage in the case where the precise form ƒ(x) of the nonlinear function in or near the channel is known; for example, where a PAR limiter is utilized and embodied by ƒ(x). Here, the nonlinear stage is characterized by the inverse ƒ_{31 1}(x) of this function. FIG. 5c illustrates a difference-based 1-D nonlinear function 518 that may characterize the nonlinear stage. This nonlinear stage embodiment may be selected for use as an alternative to the function 514 for correction of slew-rate related nonlinearities. The nonlinear stage may be implemented according to the general 1-D function 520 illustrated in FIG. 5d, depending on a number of parameters. This case would include other types of series expansions that might have advantages for particular applications and also would include spline or other methods of directly approximating the shape of a nonlinear function. In the nonlinear stage embodiment illustrated in FIG. 5e, the characterizing function 522 may be implemented as a 2-D power series for nonlinearities that cannot be reduced to 1-D such as might depend simultaneously on amplitude and slew rate. This is the most likely embodiment where the function depends on two consecutive input values. The nonlinear stage embodiment of FIG. 5f is characterized by a general function 524 in D-dimensions. The desirability of this embodiment decreases as D increases. This general case would include, for example, a power series of D input variables that includes all terms and cross terms up to some maximum power P.

As suggested by FIG. 2, additional stages 247 may be added as needed, typically alternating between the linear and nonlinear types.

The parsing of the multistage equalizer into alternating linear and nonlinear stages results in a reduction of the number of adjustable parameters required for recovery of an original signal. For example, consider a multistage equalizer architecture with three stages in which each of the two linear stages is characterized by a function of 50 input variables (that is where k₀ to k₁ spans 50 values), and in which the nonlinear stage is characterized by a function using a power series of one variable through the 5th power. With an optional constant term included in each of the linear stages, this architecture would require a total of 106 adjustable parameters. Combining the stages to form the multistage equalizer, one finds that each output value for the equalizer depends on 99 input values. Thus to obtain identical results with a single stage equalizer would require a nonlinear function to deal with 99 input variables. An appropriate nonlinear function can be created by making a 5th power expansion in 99 variables, but this requires 91,962,520 separate adjustable parameters; this number is undesirably large compared to the 106 adjustable parameters required in the example described above.

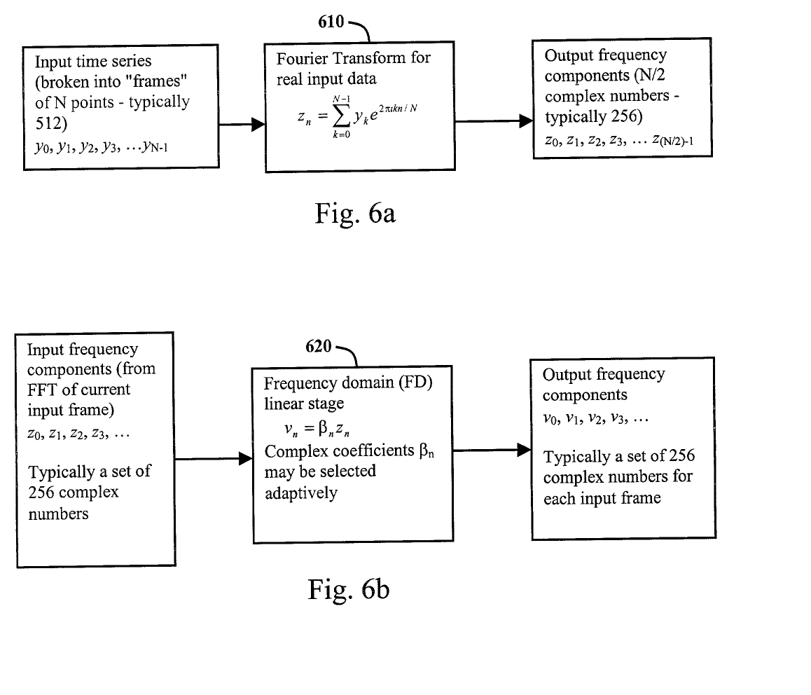

A linear stage may be implemented in the frequency domain by preceding it with a Fourier transform, such as the Fast Fourier Transform (FFT) 710 shown in FIG. 6a. In this case the linear stage is characterized by a function 620 of the form shown in FIG. 6b, which is simpler than the function 410 in FIG. 4 due to the absence of a summation. It is particularly advantageous to use this embodiment of a linear stage for the final stage of the multistage equalizer in cases where a Fourier transform is used in the demodulation process. This is true for DMT (discrete multitone) modulation that is commonly used in ADSL (asymmetric digital subscriber line) communication systems. The architecture of a multistage equalizer in such a case is depicted in FIG. 3c, which is otherwise similar to the multistage equalizer architecture of FIG. 3a. The five-stage case of FIG. 3b could be similarly modified, although this is not shown. It is also possible to create multistage equalizer architectures in which all of the linear stages are carried out in the frequency domain. In that case, each linear stage would be preceded by an FFT and each, except possibly the last, would be followed by an inverse FFT.

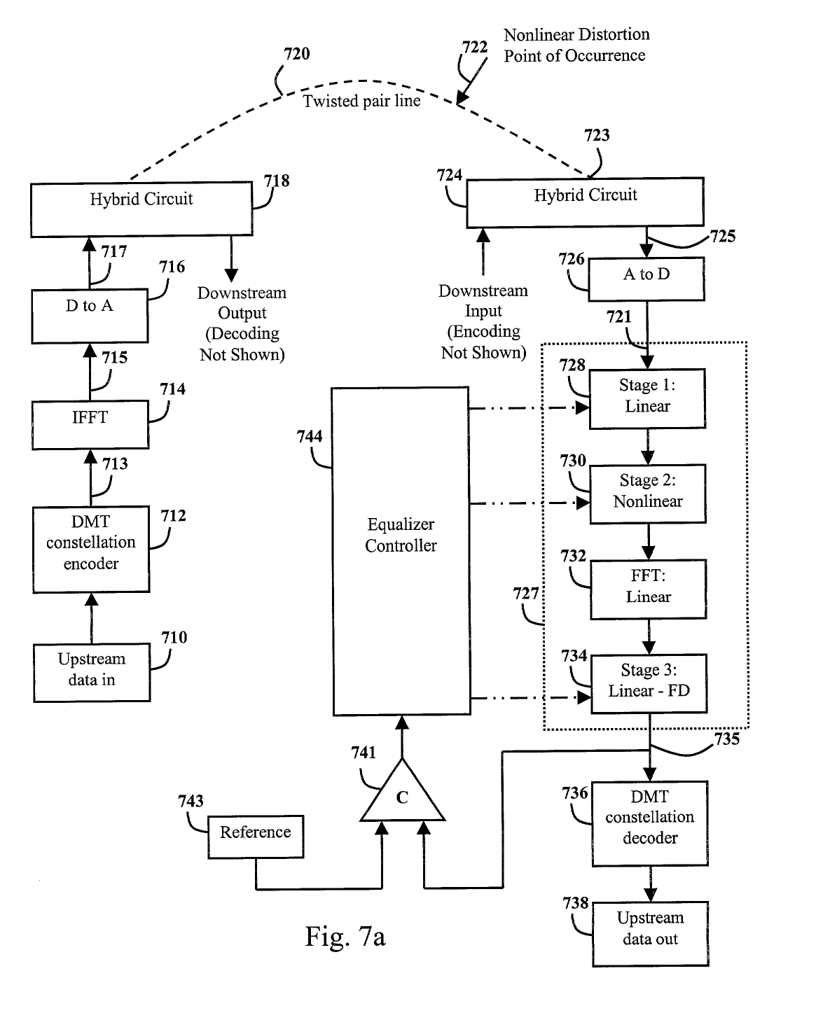

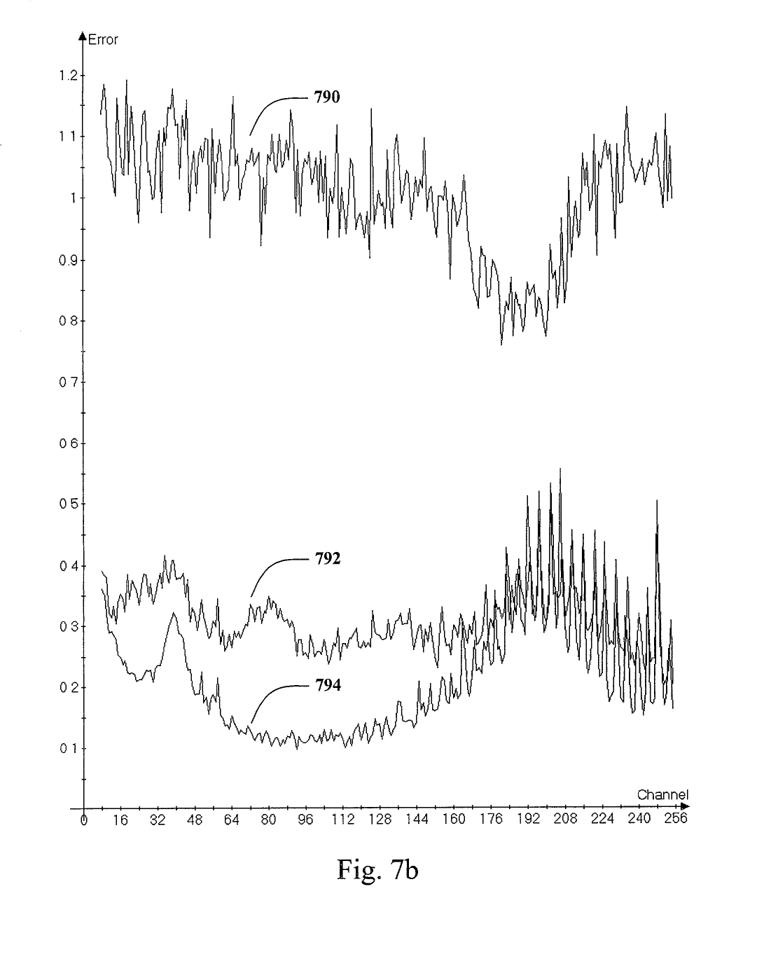

Refer now to FIG. 7a in which a specific embodiment of a digital communication system utilizing the multistage equalizer of the invention is illustrated. In FIG. 7a, an asymmetric digital subscriber line (DSL) communication system utilizes multitone signaling in which input data 710 are encoded by a discrete multitone (DMT) constellation encoder 712 into successive data symbols 713. Each symbol is expressed in the form of 256 complex numbers. These complex numbers are actually modulation parameters corresponding to the 256 data channels that these systems can support. Each complex number is allowed to take on only a discrete set of values allowing it to store a certain number of data bits in that channel. This number may vary from channel to channel and is adjusted to optimize throughput in each channel. The successive symbols are each converted by an inverse fast Fourier transform (IFFT) circuit or processor 714 into blocks of 612 time domain samples 715 which can be understood to represent a waveform made up of the sum of 256 modulated carriers at 256 distinct frequencies. These time domain samples 715 are serialized and drive a DAC 716. The analog signal 717 produced by the DAC 716 is provided to a power amplifier in a hybrid circuit 718. The amplified analog signal 719 produced by the power amplifier is coupled to and transmitted through a channel 720 constituted from a twisted pair of insulated copper wires. The existence of a source of non-linear distortion 722 at some point in the channel 720 is assumed. This distortion could have any number of causes, including characteristics of electronic components associated with the channel, and does not have to occur near the middle of the channel as shown but could occur at or near its beginning or end. Analog signals 723 transmitted through the channel 720 enter the receiver section of a hybrid circuit 724 and are provided at 725 from there to an ADC 726. From the ADC 726, received time domain digital values 721, representing a transmitted analog signal degraded by linear and nonlinear distortion, are provided to a multistage equalizer 727 according to the invention. The multistage equalizer 727 has an architecture (illustrated in FIG. 3c) that is adapted for the DMT modulation employed by the DSL system of FIG. 7a. The multistage equalizer 727 includes a first, linear stage 728 followed by a second, nonlinear stage 730. The first, linear stage 728 corrects the received digital values for linear distortion imposed by the channel 720 between the source of nonlinear distortion 722 and the ADC 726, while the nonlinear section 730 corrects them for the nonlinear distortion imposed by the source 722. Next, the time domain digital values are grouped into blocks of 512 values and processed by a fast Fourier transform (FFT) circuit or processor 732, producing a set of 256 complex numbers—a frequency domain representation of the transmitted analog signal, corrected for nonlinear distortion and linear distortion which follows it. These complex values are provided to a third, linear stage 734, of the type shown in FIG. 6b, of the multistage equalizer 727, which corrects for linear distortion caused by transmission in the signal path between 716 and 722. This output represents the extracted modulation parameters. These values are compared to those of the allowed symbol values and the closest matching symbol is selected and converted back into data bits in the DMT constellation decoder 736, which produces output data 738.

The multistage equalizer 727 is controlled or configured by an equalizer controller 744, which sets and changes the values of parameters in the functions that characterize the three stages 728, 730, and 734. In this regard, values of parameters of the functions are set, and may be changed, by the controller 744 to adapt the performance of the multistage equalizer 727 to various conditions near and in the channel 720 that distort signals transmitted in the channel. Using data from a known sequence of data symbols that was transmitted through the channel, decisions about coefficient values are made by the controller 744 in response to an error measure generated by a comparator 741. The error measure may be the result of a least square comparison of the extracted modulation parameters 735 with the expected values corresponding to the known sequence of transmitted symbols stored at the comparator 741 as a reference 743.

FIG. 7b presents an example of what can be accomplished with the multistage equalizer of this invention. The system of FIG. 7a was implemented in software and a standard DMT signal modulated with known data was transmitted through an actual 2000 foot long twisted pair line and received for processing at the other end. Prior to transmission, a parallel combination of a silicon diode and a 100 ohm resistor was inserted at a point near the beginning of the line 720 (i.e. near the hybrid circuit 718). This modeled a corroded contact in the line with non-ohmic characteristics. The error rate in the received demodulated data was measured at 741. The upper curve 790 in FIG. 7b was obtained after replacing the multistage equalizer 727 with an ordinary linear equalizer. The curve 790 shows the error level in recovering each of the active channels in the DMT signal. Next, the multistage equalizer 727 was placed back into the DSL system depicted in FIG. 7a, yielding the middle curve 782 with substantially improved error level for all channels. (The multistage equalizer 727 used a first linear stage with 35 coefficients and a nonlinear stage using a 1-D power series through seventh power.) The bottom curve 794 is provided as a reference—it was obtained by removing the diode from the line so there was no longer a nonlinear effect in the channel.

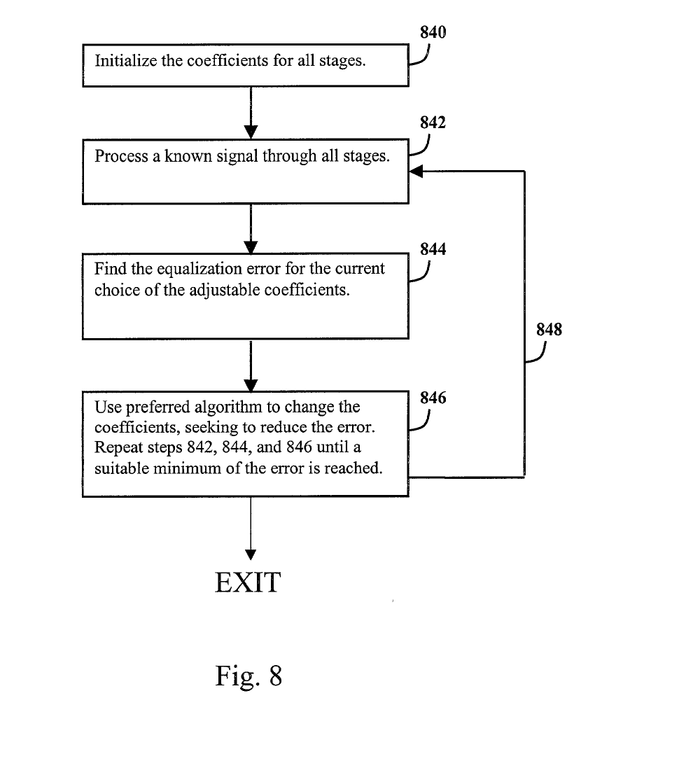

Refer now to FIG. 8 for an example of how a multistage equalizer according to this invention might be initially configured for operation. Since it utilizes optimization technology, the process of FIG. 8 may be referred to as an optimization process. The figure is a flow diagram that embodies processing performed by an equalizer controller in response to the value of an error measure generated by the comparator. The explanation presumes standard architecture for the various stages of the multistage equalizer that are concretely characterized by the functions illustrated in FIGS. 4, 5a-5f, and 6b. These architectures may be implemented in any of a number of forms, including (without limitation) software routines executed by general or special purpose digital processors, programmable logic, application specific integrated circuits (ASIC), digital signal processors (DSP), and any and all equivalents. Typically, these functions are implemented in sequentially-connected arrays of storage cells in which the cells are accessed by taps in order to obtain the values stored in those cells for combination (usually multiplication) with coefficients. The values of the coefficients are stored in locations that may be accessed for the purpose of setting and changing those values. The IFFT and the FFT included in the DSL system illustrated in FIG. 7 are similarly implemented and configured.

In FIG. 8, a multistage equalizer according to the invention is initialized in step 840. By initialization is meant that the values of all parameters for each function are set to some predetermined initial value. One choice is to initially set the parameters to values that allow the input signal to transfer to the output with little or no change. For example the linear stage of FIG. 4 could be initialized by choosing one of the parameters αₖ to set to 1 and setting all others, including the constant A, to 0. The nonlinear stage of FIG. 5a can be initialized by setting all parameters to 0. These choices will have the effect of starting the optimization with parameters that are equivalent to having no equalizer at all. Another choice is to use as a starting point the best values for the parameters that were obtained on a previous optimization attempt. Then, in step 842, a known signal, usually containing a pseudo-random sequence of data that has been transmitted through the channel, received, and stored is processed by the multistage equalizer. Using an error measure 844, typically the least square measure of the error generated by the comparator (255 of FIG. 2), and a particular optimization routine (e.g. a modified Powell routine), a new set of values of the function parameters is chosen in step 846. The routine repeatedly loops at 848 through steps 842, 844, 846, each time reprocessing the stored data set through the stages with a new set of parameters, until the error measure converges to a minimum. The parameters are then fixed and can be used to equalize the incoming signal for the real (unknown) data.

There are some worthwhile refinements to this optimization process. By deploying a duplicate multistage equalizer, it is possible to work on optimizing a new set of parameters while simultaneously continuing to use a current set so as not to interrupt the flow of real data during this process. If a large number of parameters is involved, the optimization procedure can slow, so having this ability will prevent the occurrence of lengthy periods during which no data can be processed. In the event that there is no current set of satisfactory parameters, the preferred method would be to rapidly calculate a rough but functional set of parameters that can be used while a more highly optimized set is being calculated. Another refinement is to break the optimization process into two (or possibly more) loops. This is particularly effective if the final stage is a linear one. In this case, a full optimization can be run on the parameters in the final stage alone while holding the others fixed. Being linear, this can be accomplished very rapidly in a fast inner loop. The other parameters are adjusted by a slow outer loop using a different optimization routine. For every pass through the slow loop, the parameters in the final stage are fully optimized again by the fast loop. Note that the fast loop could be replaced by a direct calculation of the optimal parameters for the final stage using for example the technique of singular value decomposition.

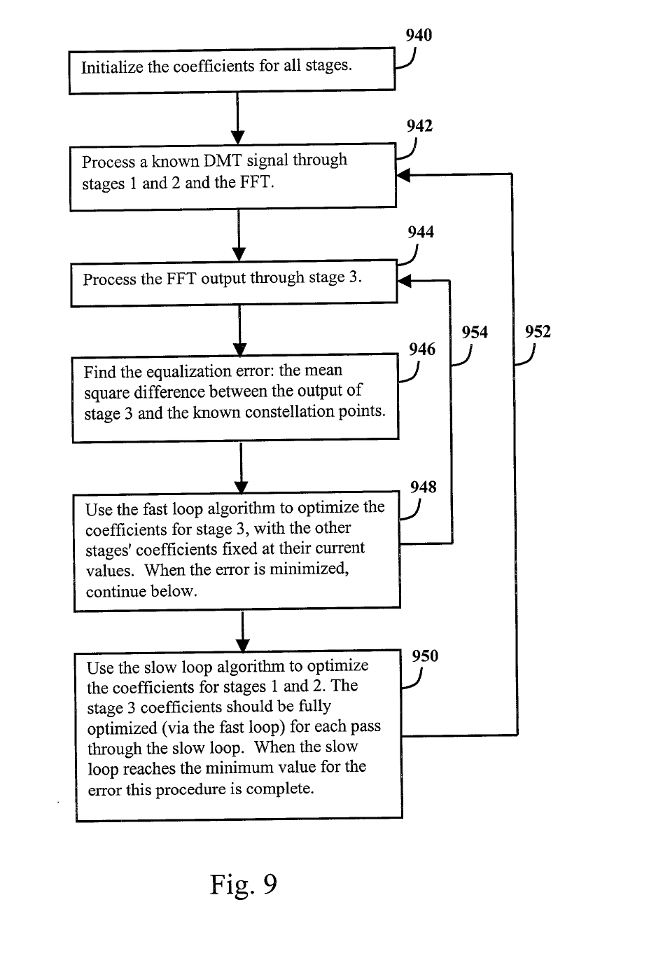

A dual loop optimization process with a fast inner loop is illustrated in FIG. 9 as an initialization routine adapted for DMT modulation in the DSL system of FIG. 7a. In this case, the coefficients of all stages are initialized in step 940 and a received and stored DMT modulated signal of a known data set, is processed through the stages 728 and 730 in step 942, then by the FFT 732 in step 944, and then through stage 734 in step 946. In step 946, the least square error is determined. Using the least square error, a fast loop algorithm (such as a conjugate gradient optimization algorithm) optimizes the coefficients of stage 734 in step 948, and loops back to step 944. The fast loop 954 is traversed until it reaches a minimum error, when the routine moves to step 950. In step 950, the slow loop algorithm (such as the modified Powell method) is used to optimize the coefficients for the stages 728 and 730, and the outer loop 952 is traversed. With each traversal of the loop 952, steps 944, 946, and 948 are performed in sequence and iterated via the loop 954. Step 950 is then executed and the routine operates until minimum error value is reached. Assuming this minimum is satisfactory, the resultant set of parameter values is ready for use.

Note that for nonlinear functions as may be used in this multistage equalizer, finding the set of coefficients that produce the minimal error may produce “local minima” which are not as small as a true “global minimum”. There are well-known techniques for resolving such ambiguities. It may be necessary to start the optimization process from a variety of initial conditions or to use a somewhat slower optimization routine which is intended to find a global minimum. Some useful techniques may include, without limitation, a modified Powell method, a conjugate gradient method, multidimensional dithering and simulated annealing. These and other means and methods for optimization and minimization may be found, for example, in “Numerical Recipes in C: The Art of Scientific Computing” by William Press, et al., Cambridge University Press, 1993.

I Claim:

1. A multistage equalizer, comprising:
at least two stages connected in a sequence;
each stage having an input and an output, the input of any stage following another stage in the sequence being connected to the output of the other stage;
each stage being characterized by a respective function that, in response to an input digital time series x₁, X₂, X₃, . . . , produces an output digital time series y₁, Y₂, Y₃, . . . , the value of any element of the output time series depending on the values of one or more of the elements of the input series; and
the sequence causing at least two stages to alternate in their respective functions between linear functions and nonlinear functions.

2. The multistage equalizer of claim 1, wherein the sequence begins with a first stage characterized by a linear function, followed by at least a second stage characterized by a nonlinear function.

3. The multistage equalizer of claim 2, wherein the sequence continues with one or more stages following the second stage, the respective functions of the one or more stages alternating in the sequence (linear,nonlinear,linear, . . . ).

4. The multistage equalizer of claim 1, wherein the sequence begins with a first stage characterized by a nonlinear function, followed by at least a second stage characterized by a linear function.

5. The multistage equalizer of claim 4, wherein the sequence continues with one or more stages following the second stage, the respective functions of the one or more stages alternating in the sequence (nonlinear,linear,nonlinear, . . . ).

6. The multistage equalizer of claim 1, in which the linear functions include the function:
$${x}_{n} = A + {\sum }_{k = {k}_{0}}^{{k}_{1}} {α}_{k} {u}_{n + k}$$
where A is a constant and αₖ is a parameter of the function, the parameter having a settable value.

7. The multistage equalizer of claim 1 in which one or more of the nonlinear functions are functions in the group including: a one-dimensional power series function; an inverse of a known non-linear function; an inverse of a known piecewise linear function; a one-dimensional, difference-based power series function of degree P; a one-dimensional function depending on k parameters; a two-dimensional power series of degree P; and, a D-dimensional function, depending on k parameters.

8. A multistage equalizer, comprising:
at least a first stage characterized by a first function to produce first results correcting linear distortion in a signal transmitted through a dispersive channel; and
at least a second stage coupled to the first stage, the second stage characterized by a second function to produce from the first results second results correcting nonlinear distortion in the signal.

9. The multistage equalizer of claim 8, further comprising at least a third stage coupled to the second stage, the third stage characterized by a second function to produce from the second results third results correcting linear distortion in the signal.

10. The multistage equalizer of claim 8, wherein the first function is a linear function for correcting linear distortion which occurs in the channel following the nonlinear distortion.

11. The multistage equalizer of claim 10, further including at least a third stage coupled to the second stage, the third stage characterized by the first function to produce from the second results third results correcting linear distortion in the signal which occurs in the channel preceding the nonlinear distortion.

12. The multistage equalizer of claim 11, in which the first and third stages are linear, time domain equalizers.

13. The multistage equalizer of claim 8, in which the second function is one of the set including: a one-dimensional power series function; an inverse of a known non-linear function; an inverse of a known piecewise linear function; a one-dimensional, difference-based power series function of degree P; a one-dimensional function depending on k parameters; a two-dimensional power series of degree P; and, a D-dimensional function, depending on k parameters.

14. The multistage equalizer of claim 8, wherein the second results are time domain signals, further including: a means coupled to the second stage for converting the second results from the time to the frequency domain; and, a third stage coupled to the means, the third stage characterized by a third function to produce from the second results third results in the frequency domain correcting linear distortion in the signal.

15. The multistage equalizer of claim 14, wherein the first stage is a linear, time domain equalizer and the third stage is a linear frequency domain equalizer.

16. The multistage equalizer of claim 15, in which the second function is one of the set including: a one-dimensional power series function; an inverse of a known non-linear function; an inverse of a known piecewise linear function; a one-dimensional, difference-based power series function of degree P; a one-dimensional function depending on k parameters; a two-dimensional power series of degree P; and, a D-dimensional function, depending on k parameters.

17. The multistage equalizer of claim 14, in which the second function is one of the set including: a one-dimensional power series function; an inverse of a known non-linear function; an inverse of a known piecewise linear function; a one-dimensional, difference-based power series function of degree P; a one-dimensional function depending on k parameters; a two-dimensional power series of degree P; and, a D-dimensional function, depending on k parameters.

18. In a digital communication or storage system in which digitally-modulated signals are transferred through a dispersive medium, the combination including:
an analog to digital converter;
a line receiver for coupling a digitally-modulated analog signal from the dispersive medium to the converter; and
a multistage equalizer coupled to receive a digital signal produced by the converter in response to the analog signal and to correct the digital signal for linear and nonlinear distortion of the analog signal.

19. The combination of claim 18, the multistage equalizer comprising:
at least a first stage characterized by a first function to produce first results
correcting linear distortion of the analog signal; and
at least a second stage coupled to the first stage, the second stage characterized by a second function to produce from the first results second results correcting nonlinear distortion of the analog signal.

20. The combination of claim 19, wherein the first function is a linear function for correcting linear distortion which occurs in the channel following the nonlinear distortion.

21. The combination of claim 19, the multistage equalizer further comprising at least a third stage coupled to the second stage, the third stage characterized by a second function to produce from the second results third results correcting linear distortion in the signal.

22. The combination of claim 21, further including at least a third stage coupled to the second stage, the third stage characterized by the linear function to produce from the second results third results correcting linear distortion in the signal which occurs in the channel preceding the nonlinear distortion.

23. The combination of claim 22, in which the first and third stages are linear, time domain equalizers.

24. The combination of claim 19, in which the second function is one of the set including: a one-dimensional power series function; an inverse of a known non-linear function; an inverse of a known piecewise linear function; a one-dimensional, difference-based power series function of degree P; a one-dimensional function depending on k parameters; a two-dimensional power series of degree P; and, a D-dimensional function, depending on k parameters.

25. The combination of claim 19, wherein the second results are time domain signals, further including: a means coupled to the second stage for converting the second results from the time to the frequency domain; and, a third stage coupled to the means, the third stage characterized by a third function to produce from the second results third results in the frequency domain correcting linear distortion in the signal.

26. The combination of claim 25, wherein the first stage is a linear, time domain equalizer and the third stage is a linear, frequency domain equalizer.

27. The combination of claim 26, in which the second function is one of the set including: a one-dimensional power series function; an inverse of a known non-linear function; an inverse of a known piecewise linear function; a one-dimensional, difference-based power series function of degree P; a one-dimensional function depending on k parameters; a two-dimensional power series of degree P; and, a D-dimensional function, depending on k parameters.

28. The combination of claim 25, in which the second function is one of the set including: a one-dimensional power series function; an inverse of a known non-linear function; an inverse of a known piecewise linear function; a one-dimensional, difference-based power series function of degree P; a one-dimensional function depending on k parameters; a two-dimensional power series of degree P; and, a D-dimensional function, depending on k parameters.

29. An equalizing apparatus for use in a digital communication or storage system, comprising:
a multistage equalizer having at least a first stage characterized by a first function to produce first results correcting linear distortion in a signal transmitted through a dispersive channel, and at least a second stage coupled to the first stage, the second stage characterized by a second function to produce from the first results second results correcting nonlinear distortion in the signal;
an equalizer controller coupled to the first stage and to the second stage for setting values of parameters of the first function and the second function in response to an error measure value; and
an error measure value generator coupled to the equalizer controller.

30. The equalizing apparatus of claim 29, the multistage equalizer further having at least a third stage coupled to the second stage, the third stage characterized by a second function to produce from the second results third results correcting linear distortion in the signal.

31. The equalizing apparatus of claim 29, wherein the first function is a linear function is for correcting linear distortion which occurs in the channel following the nonlinear distortion.

32. The equalizing apparatus of claim 31, the multistage equalizer further having at least a third stage coupled to the second stage, the third stage characterized by the linear function to produce from the second results third results correcting linear distortion in the signal which occurs in the channel preceding the nonlinear distortion.

33. The equalizing apparatus of claim 32, in which the first and third stages are linear, time domain equalizers.

34. The equalizing apparatus of claim 29, in which the second function is one of the set including: a one-dimensional power series function; an inverse of a known non-linear function; an inverse of a known piecewise linear function; a one-dimensional, difference-based power series function of degree P; a one-dimensional function depending on k parameters; a two-dimensional power series of degree P; and, a D-dimensional function, depending on k parameters.

35. The equalizing apparatus of claim 29, wherein the second results are time domain signals, the multistage equalizer further having: a means coupled to the second stage for converting the second results from the time to the frequency domain; and, a third stage coupled to the means, the third stage characterized by a third function to produce from the second results third results in the frequency domain correcting linear distortion in the signal.

36. The equalizing apparatus of claim 35, wherein the first stage is a linear, time domain equalizer and the third stage is a linear, frequency domain equalizer.

37. The equalizing apparatus of claim 36, in which the second function is one of the set including: a one-dimensional power series function; an inverse of a known non-linear function; an inverse of a known piecewise linear function; a one-dimensional, difference-based power series function of degree P; a one-dimensional function depending on k parameters; a two-dimensional power series of degree P; and, a D-dimensional function, depending on k parameters.

38. The equalizing apparatus of claim 35, in which the second function is one of the set including: a one-dimensional power series function; an inverse of a known non-linear function; an inverse of a known piecewise linear function; a one-dimensional, difference-based power series function of degree P; a one-dimensional function depending on k parameters; a two-dimensional power series of degree P; and, a D-dimensional function, depending on k parameters.

39. A method of optimizing a multistage equalizer to correct distortion in a digitally-modulated signal transmitted in a dispersive medium, the multistage equalizer constituted of a plurality of stages, in which:
at least two of the stages are connected in a sequence;
each stage has an input and an output, the input of any stage following another stage in the sequence being connected to the output of the other stage;
each stage is characterized by a respective function that, in response to an input digital time series x₁, x₂, x₃, . . . , produces an output digital time series y₁, y₂, Y₃, . . . , the value of any element of the output series depending on the values of one or more of the elements of the input series;
the sequence causes the at least two stages to alternate in their respective functions between linear functions and nonlinear functions; and,
at least one function includes one or more parameters with settable values,
the method characterized by:
setting the parameters of at least a first function which characterizes one stage of the multistage equalizer to first predetermined values;
setting the parameters of functions which characterize the remaining stages to second predetermined values:
receiving a digitally-modulated signal from a dispersive medium;
converting the digitally-modulated signal to a digital form; and then
(a) processing the digital form with the multistage equalizer to an equalized digital form;
(b) producing an error measure by comparing the equalized digital form to a known digital form; and
(c) changing the values of the parameters of the first function in response to the error measure.

40. The method of claim 39, further characterized by optimizing the error measure and the values of the parameters of the first function in a first loop which iterates (a)-(c).

41. The method of claim 40, further characterized by setting the parameters of a plurality of second functions which characterize other stages from zero to predetermined values, and then:
(d) changing the values of the parameters of the second functions in response to the error measure; and,
(e) repeating (a)-(c).

42. The method of claim 41, further characterized by optimizing the values of the parameters of the second functions in a second loop which iterates (d)-(e).

43. A method of optimizing a multistage equalizer to correct distortion in a digitally-modulated signal transmitted in a dispersive medium, the multistage equalizer constituted of a plurality of stages, in which:
at least two of the stages are connected in a sequence;
each stage has an input and an output, the input of any stage following another stage in the sequence being connected to the output of the other stage;
each stage is characterized by a respective function that, in response to an input digital time series x₁, x₂, x₃, . . . , produces an output digital time series y₁, y₂, y₃, . . . , the value of any element of the output series depending on the values of one or more of the elements of the input series;
the sequence causes the at least two stages to alternate in their respective functions between linear functions and nonlinear functions; and,
each function includes a plurality of parameters with settable values, the method characterized by:
setting the parameters of the functions which characterize the stages of the multistage equalizer to predetermined values;
receiving a digitally-modulated signal from a dispersive medium;
converting the digitally-modulated signal to digital form; and then
(a) processing the digital form with the multistage equalizer to an equalized digital form;
(b) producing an error measure by comparing the equalized digital form to a known digital form; and,
(c) changing the values of the parameters of the functions in response to the error measure.

44. The method of claim 43, further characterized by optimizing the values of the parameters of the functions in a loop which iterates (a)-(c).
